(19) United States
(12) Patent Application Publication
(10) Pub. No.: US 2010/0330278 A1
(43) Pub. Date: Dec. 30, 2010

(54) METHOD FOR TREATING HIGH HYDROPHOBIC SURFACE OF SUBSTRATE

(76) Inventors: Sung-Hwan Choi, Seoul (KR); Ki-Jeong Moon, Seoul (KR); Hae-Sang Jeon, Seoul (KR)

Correspondence Address: HARNESS, DICKEY, & PIERCE, P.L.C, 7700 Bonhomme, Suite 400, ST. LOUIS, MO, 63105, US

(21) Appl. No.: 12/862,611

(22) Filed: Aug. 24, 2010

Related U.S. Application Data
(63) Continuation of application No. PCT/KR2009/003279, filed on Jun. 18, 2009.

(30) Foreign Application Priority Data
Jun. 10, 2009 (KR) 10-2009-0051342

(51) Int. Cl. C23C 16/30

(52) U.S. Cl. 427/255.28

(57) ABSTRACT

There is provided a method for treating a surface of a substrate, comprising forming a layer, such as a mixed self-assembled monolayer (SAM), on the surface via chemical vapor deposition (CVD) with a CF₃-functionalized organic silane and a CH₃-functionalized organic silane, wherein the length of a carbon chain of the CH₃-functional organic silane is shorter than a carbon chain of the CF₃-functionalized organic silane.

### CROSS-REFERENCE TO RELATED APPLICATIONS

This application is a continuation of PCT Application No. PCT/KR2009/003279 filed on Jun. 18, 2009, which claims the benefit and priority to Korean Patent Application No. 10-2009-0051342, filed Jun. 10, 2009. The entire disclosures of the applications identified in this paragraph are incorporated herein by reference.

### FIELD

The invention relates to a method of modifying the surface of a substrate to be highly hydrophobic in order to provide the substrate with high hydrophobicity. More particularly, this method uses spontaneous phase separation during the modification of the substrate with two different types of organic silane molecules with low surface energies but having different chain lengths. The surface roughness resulted from the height difference of the domain and matrix structure formed by the phase-separated long and short low-surface energy organic silane molecules, respectively, and can mimic the ultra-hydrophobicity, known as the Lotus effect. In this way, the method can render the substrate highly hydrophobic.

### BACKGROUND

Hydrophobicity of a given surface (or having a low surface energy) is an essential property for the surface if possible. If the surface of interest is not in a special environment without humidity, water droplets are absorbed into the surface and then form discontinuous or continuous moisture films, and further thin water films. External contaminants are highly likely to be absorbed into the films formed as such. These contaminants make later surface cleaning impossible because they even more closely adhere to the surface by capillary attraction induced in evaporation after the water films are evaporated.

Such a phenomenon can be easily understood when we see the dust on the windows in a building or a vehicle or on a vehicle body after raining. If the surface is highly hydrophobic, the surface thereof is not wet with water droplets, which then tumble down and the surface is contamination-resistant. Contaminants adhered to the surface are absorbed into the water drops running down on the surface and are thus removed (the so-called self-cleaning effect). In addition, high hydrophobicity is essentially required for semiconductor elements or electronic parts/circuits, antioxidized surface treatment, antibiofouling surface treatment and microelectromechanical systems (MEMS) for the surface of goods/customer electronics generally used in daily living.

Generally, in order to implement high hydrophobicity for a surface, a composite surface roughness is required at a micrometer and nanometer level. In other words, it is to minimize water wettability while the surface energy on the relevant part is zero not only by including an organic solid surface simply having a low surface energy, but also by including “interfaces of air”. In terms of physicochemistry, the area which water actually contacts is very small on a highly rough or a porous surface including interfaces of air. Since the amount of energy obtained is very small compared to the amount of the increased surface area of water, water is absorbed into the surface, and wetting does not occur spontaneously while the water remains in a drop shape, rather than spreading over the hydrophobic surface. The relationship described above can be described with the following equation 1 which is derived by including the Wenzel equation in the Cassie equation, the Wenzel equation showing the relation of a surface roughness to a contact angle of water and the Cassie equation explaining a contact angle of water on a nonuniform surface where the interfaces of air and another surface (1) coexist at a given ratio.

cos θ_{A}=rf₁ cos θ₁−f₂ Equation 1

where θ_{A} is an apparent contact angle of water on a surface at an air interface, r is a ratio of an actual surface area to a surface area projected (Wenzel roughness, >1), f₁ is a ratio of another surface, not the interface of air, to the entire surface (<1), θ₁ is a contact angle of water on a smooth surface 1 without roughness and f₂ is a ratio of the interfaces of air to the entire surface (=1−f₁).

However, for surfaces with such a surface roughness as described above, conventionally used methods are time consuming, comprise complex processes and are costly, e.g., heavy plasma treatment, photolithography, casting, mechanical process, etc. Essentially required is further an additional process of absorbing expensive synthetic material of a low surface energy. In case of coating with particles, since bonding between the coating liquid and particles only depends on the van der Waals force among molecules which is relatively low, abrasion resistance of the coating is degraded and the coating layer is delaminated on the substrate surface. Therefore, if organic contaminants the size of dust contaminate a surface, the contaminants are not removed via self-cleaning of the highly hydrophobic surface, and surface cleaning is impossible by means of mechanical friction. As a result, high hydrophobicity of the surface is significantly deteriorated over time from contamination.

As described above, technologies described above are disadvantageous in terms of technical complexity, low production efficiency, low heat resistance, chemical resistance, durability, abrasion resistance, etc. A method for treating and producing a highly hydrophobic surface with the properties required in order to overcome these disadvantages and limitations through a simpler process.

### SUMMARY

This disclosure addresses the aforementioned problems. It is an object of this disclosure to provide a method for producing a highly hydrophobic surface in a simple and efficient manner and, in addition, to provide a method of treating a surface to be highly hydrophobic applicable to the fields requiring surface properties such as contamination resistance, heat resistance, chemical resistance, abrasion resistance, durability, etc.

The aforementioned and other objects and features of the disclosure will be more apparent from the following description.

The aforementioned object is achieved by a method of producing a surface to a substrate and treating it to be highly hydrophobic, wherein the highly hydrophobic surface is obtained by forming a mixed self-assembled monolayer (SAM) through chemical vapor deposition with a CF₃-functionalized organic silane (i.e., an organic silane having CF₃ group as a functional group) and a CH₃-functionalized organic silane (i.e., an organic silane having CH₃ group as a functional group) wherein the carbon chain of the CH₃-functionalized organic silane is shorter than the carbon chain of the CF₃-functionalized organic silane.

The method is characterized in that the substrate is selected from the group consisting of quartz, silicon wafer, glass, ceramic, glass-ceramic, inorganic metallic oxide or activated plastic, and a film thereof.

In some embodiments, the method is characterized in that the lotus effect is implemented via phase separation that spontaneously occurs in the process of surface bonding between the CF₃-functionalized organic silane and the CH₃-functionalized organic silane in order to attain high hydrophobicity.

In other embodiments, the method is characterized in that the chemical formula of the CF₃-functionalized organic silane is F₃C(CF₂)ₐ(CH₂)_{b}SiX₃, wherein a ranges from 5 to 20, b ranges from 2 to 5, and X is chloride, methoxy or ethoxy; and the chemical formula of the CH₃-functionalized organic silane is H₃C(CH₂)_{c}SiX₃, wherein c ranges from 7 to 23 and X is chloride, methoxy or ethoxy.

In yet other embodiments, the method is characterized in that the difference in the number of carbons in the carbon chains of the CF₃-functionalized organic silane and the CH₃-functionalized organic silane is at least 2, so that the difference in height of the phase made of each organic silane in the mixed self-assembled monolayer leads to high hydrophobicity.

In some embodiments, the method is characterized in that it further comprises a curing process after chemical vapor deposition in order to enhance bonding of the organic silanes to the substrate. In a particular aspect of this embodiment, the root mean square (RMS) value of the surface roughness produced by the organic silanes ranges from 0.5 nm to 1 nm.

According to this disclosure, with two types of hydrophobic/highly hydrophobic functional groups and organic silanes different in the length of carbon chains, a surface roughness is obtained via natural/spontaneous surface bonding to a substrate having a reaction site and phase separation, the reaction site being able to react with organic silanes such as a hydroxyl group. The hydrophobic surface with a roughness obtained as such has a lotus effect and is thus highly hydrophobic. Accordingly, such a highly hydrophobic surface intrinsically contamination resistant, and provides a coating that is not achieved in conventional highly hydrophobic surface treatment manners, e.g., heat resistance, abrasion resistance, durability, chemical resistance, etc., contributed by organic silanes.

### DESCRIPTION OF THE DRAWINGS

The features and advantages of the present invention will become apparent from the following detailed description of a preferred embodiment thereof illustrated with reference to the accompanying drawings.

FIG. 1 shows a concept of a mixed self-assembled monolayer, wherein A1 is CF₃ functional group, A2 is a CF₂ moiety, A3 is a CH₂ moiety, A4 is CH₃ functional group, and A5 is a substrate including hydroxyl groups thereon.

FIG. 2 shows photographs of a contact angle of a hydrophobic surface according to an embodiment (left) and of the comparative example (right).

FIG. 3 shows microscopic images of friction atomic force for the surface according to an embodiment (A8) and the comparative example (A9).

### DETAILED DESCRIPTION

Hereinafter, the disclosure will be described in more detail with reference to the embodiment and the drawings. The embodiment is intended to illustrate the disclosure in more detail, and the scope should not be limited by the embodiment.

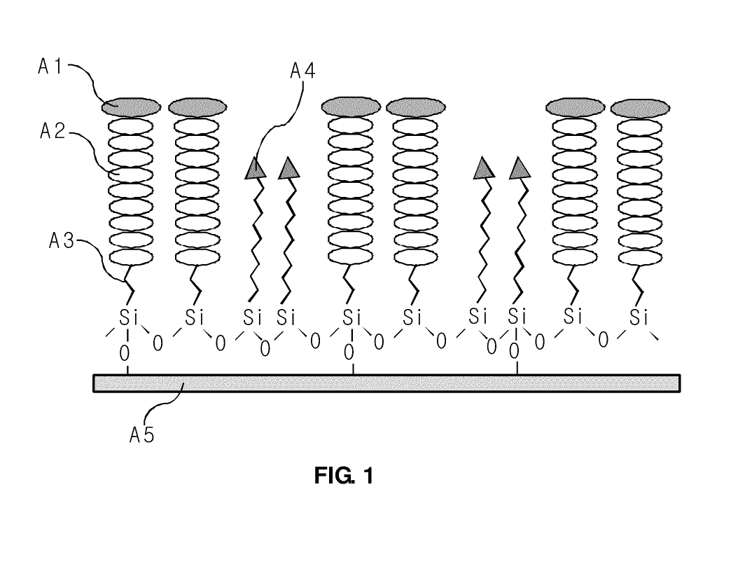

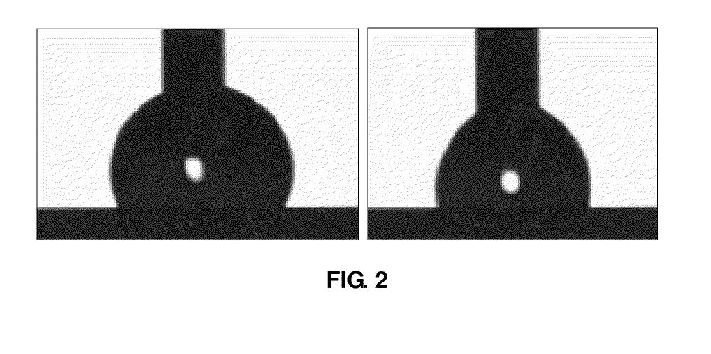

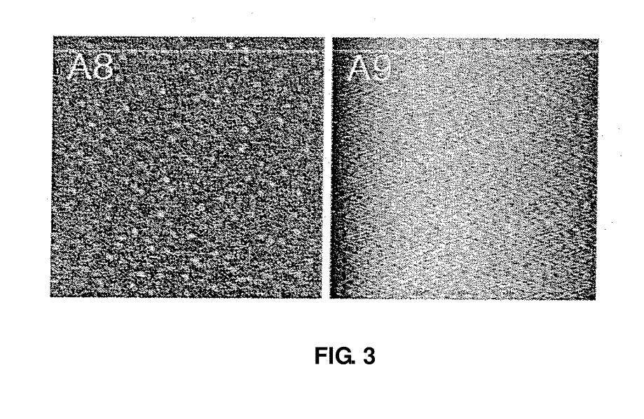

FIG. 1 shows a concept of a mixed self-assembled monolayer consisting of a domain and matrix structure derived through phase separation which spontaneously occurred in the process of treating a surface by chemical vapor deposition of perfluoroalkylsilane and alkylsilane with a shorter carbon chain than the perfluoroalkylsilane. In the drawing, the combination of organic silanes or the Si—O combinations derived by bonding to a substrate is simplified to 2-D. FIG. 2 shows a photograph of a contact angle of a hydrophobic surface according to an embodiment (left) and that of a contact angle of a hydrophobic surface according to the comparative example (right). The contact angles were measured while the needle of a syringe containing water was in a waterdrop. FIG. 3 shows a friction atomic force microscopic image according to an embodiment (A8, left) and a friction atomic force microscopic image (A9, right) according to the comparative example.

The method of treating a surface of substrate to be highly hydrophobic, relates to treating the surface to be combined to the substrate to be highly hydrophobic, wherein high hydrophobicity is obtained by forming a mixed self-assembled monolayer by means of chemical vapor deposition with a CF₃-functionalized organic silane and a CH₃-functionalized organic silane shorter in the length of a carbon chain than that of the CF₃-functionalized silane.

The method of treating a surface of substrate to be highly hydrophobic attains high hydrophobicity, using two types of organic silanes having a different terminal functional group or carbon chain lengths, wherein the two types of organic silane react with the substrate to be coated therewith. The organic silane consisting of CF₃ and CF₂ is better in hydrophobicity and forms a domain or island via spontaneous phase separation in coating. The organic silane consisting of CH₃ and CH₂ forms a matrix smaller in thickness in order to achieve the lotus effect, having a low surface energy component and a high surface roughness and thus to achieve high hydrophobicity. In particular, coating can be implemented with advantageous durability, abrasion resistance, heat resistance, and chemical resistance as well as high hydrophobicity and contamination resistance by using organic silanes which covalently bond to a substrate (FIG. 1).

In the method of treating a surface of substrate to be highly hydrophobic, the substrate to be surface-treated may comprise quartz, silicon wafer, glass, ceramic, glass-ceramic, inorganic metallic oxide or activated plastics, and a film thereof or, an oxidized surface thereof, provided that it has a hydroxyl group to enable dehydration-condensation reaction with the organic silanes. To enhance the feature or efficiency of surface treatment, the substrate may go through an additional oxidization process, e.g., plasma treatment, UV irradiation, piranha solution (H₂SO₄/H₂O₂=70/30 v/v) treatment, etc.

The two types of organic silane used for highly hydrophobic surface treatment or coating a substrate are generally available in the market and the former organic silane (OS1) is linear fluoroalkylsilane. The chemical formula thereof is shown below:

F₃C(CF₂)ₐ(CH₂)_{b}SiX₃

wherein a ranges from 5 to 20, b ranges from 2 to 5, and X is chloride, methoxy or ethoxy. A sum of a and b not more than 7 leads to a lowered inter-silane molecule van der Waals bond force, lowered cohesion of molecules in the self-assembled monolayer, and lowered hydrophobicity, heat resistance and durability. CF₃ at the end is the outermost functional group exposed after surface treatment and determines the features of the surface. The surface energy value of the silane is 11 mJ/m² or so. X is a reaction group of the silane and is hydrolyzed and substituted by a hydroxyl group. The substituted hydroxyl group then goes through dehydration-condensation reaction with the hydroxyl group on the surface of substrate to have a strong siloxane bond of —Si—O—. If there are 3 different types of X group, each molecule exhibits a significant difference in substitution ratios by a hydroxyl group or reactivity to bond each other but build up a 3 dimensional complex and loose structure, not forming a monolayer systematically. While all of the functional groups are not exposed to the outermost surface, but a part is buried in this structure, high hydrophobicity and other properties are degraded.

The latter silane (OS2) is alkylsilane having a linear structure with the following chemical formula:

H₃C(CH₂)_{c}SiX₃

wherein c ranges from 7 to 23 and X is chloride, methoxy or ethoxy. In particular, each X is the same type of group for the same reason as for OS1. If c is not more than 7, the van der Waals force is not sufficient among carbon chains of the molecules bonded to the substrate, so that the chains may not be fully extended and then lay on the substrate or be bent. When molecular cohesion to the surface is degraded, some water on the molecular layer permeates into the molecular layer to the highly hydrophilic hydroxyl groups not bonded to the substrate, thus deteriorating hydrophobicity. OS2 does not directly contact water but reacts with the highly hydrophilic hydroxyl groups that do not react with the OS1 in the substrate, efficiently shielding the surface from water. OS2 assumes an important role so that OS1 is phase-separated with an island or domain structure. The difference in the number of carbons in the carbon chains between OS1 and OS2 must be at least 2 so that OS2 may form a matrix while having a difference in step height from OS1. The surface energy of CH₃ is approximately 21 mJ/m² or so.

The aforementioned two organic silanes are absorbed/combined into/with the oxidized substrate via chemical vapor deposition (CVD). Since the inter-molecular van der Waals force or bonding force of OS1 having a carbon chain containing fluorine groups and in which the length of the chain is longer, is stronger than that of OS2 having only an alkyl group in which the length of the carbon chain is shorter, OS1 thereby attracts the same molecules first to form islands in a domain structure. During the process, OS2 fills the gaps between the domain structures to form matrices. As such, easy and natural phase separation is enabled with an absorption/reaction speed difference into/with the substrate by two different types of organic silanes and spontaneously forming a monolayer of organic silane. That is, the difference in mutual action force among molecules in the two silanes leads to spontaneous micro-phase separation when bonding to the substrate. The fluorinated organic silane with longer carbon chains forms domains or islands which protrude naturally or selectively compared to the alkyl silane.

This process enables a highly hydrophobic surface naturally and spontaneously to be implemented without artificial additional processes, e.g., synthesis of new organic materials, producing a high surface roughness or a porous structure, masking, application of particles, irradiation of energy rays, etc., typically used to achieve the lotus effect superhydrophobicity by combination of a high surface roughness and a low surface energy.

In this disclosure, bonding between silanes and the substrate after treatment may be enhanced by additionally curing the substrate. Temperature for curing ranges from room temperature to about 170° C., and generally from 80° C. to 150° C. The higher the temperature is, the less the time necessary for hardening. Time taken is about 5 hours at 80° C. and about one hour at 170° C. To obtain more solid monolayers, the silane molecules which are physically absorbed thus to form a multilayer can be washed out with general organic solvents (e.g., hexane, toluene, alcohol, acetone, etc.) or can be removed by immersing the substrate in an organic solvent and then with an ultrasonicator.

The method of treating a surface of substrate to be highly hydrophobic has a root mean square (RMS) value of surface roughness produced with the organic silanes ranges 0.5 nm to 1 nm. If the RMS value is less than 0.5 nm, the effect of surface roughness cannot be attained, including interfaces of air, and hydrophobicity is thus degraded. If the surface roughness is greater than 1 nm, the mixed self-assembled monolayer does not form a monolayer but forms a sparse multilayer, so that the inter-molecular bonding force or cohesion is degraded while the properties of durability, chemical resistance, abrasion resistance and heat resistance is deteriorated.

### Example

A silicon wafer (silicon wafer, 5 cm×5 cm) was used for the substrate for highly hydrophobic surface treatment. The wafer was immersed in the piranha solution (H₂SO₄/H₂O₂=70/30 v/v) for about 30 minutes to remove contaminants on the surface and to activate the hydroxyl groups. The wafer was then taken out, fully rinsed with deionized (DI) water, and blown dry with nitrogen gas. The two types of organic silane used in the embodiment were CF₃(CF₂)₁₀(CH₂)₂SiCl₃ (FTCS) and CH₃(CH₂)₉SiCl₃ (DTCS). The air bubbles in the solution were removed while keeping the pressure in a desiccator at 10 mTorr with a vacuum pump after putting and sufficiently stirring 200 μl of the two types of organic silane in 3 g of mineral oil and then putting the mixture in the desiccator. If chemical vapor deposition is directly carried out without removing the air bubbles in advance, when the pressure is lowered, the air bubbles suddenly boil and irregular and nonuniform evaporation of the organic silane molecules may adversely affect the quality of the coating layer. For this reason, the solution is degassed before vacuum release. The piranha-etched side of the silicon wafer is the side to be surface-treated, is faced toward the surface of the solution, and is hung in the chamber. Thereafter, the chamber was evacuated again to keep the pressure at 10 mTorr. Deposition is carried out for about one hour. The surface-treated silicon wafer was placed in an oven to cure it at 80° C. for about 5 hours. The silicon wafer was then immersed in a hexane solvent to be cleaned with an ultrasonic cleaner for about 2 minutes to remove organic silane molecules that might be physically absorbed thereon. The silicon wafer was then blown dry with nitrogen gas.

### Comparative Example

In the comparative example, chemical vapor deposition only with CF₃(CF₂)₁₀(CH₂)₂SiCl₃ was applied to the silicon wafer cleaned with the piranha solution in the same manner as above. Both of curing and ultrasonic cleaning was applied the same as above.

TABLE 1

| | | Comparative | |
|---|---|---|---|
| | Example | Example | Remarks |
| Contact angle of DI water (°) | 120 | 105 | FIG. 2 |
| Contact angle hysteresis | 5 | 15 | — |
| Microscopic image of | Island structure by | No structure | FIG. 3 |
| friction atomic force (AFM) | phase separation | | |

For mixed self-assembled monolayer formed with FTCS and DTCS, the water contact angle was greater than that of the monolayer formed only with FTCS (FIG. 2). The fact that the surface energy of a functional group in the mixed monolayer was 11 and 21 mJ/m² which is the same or greater than that of the monolayer formed only with FTCS but exhibited lower surface energy indirectly illustrates that the lotus effect resulted from phase separation in the two types of organic silane.

High surface friction in case of surface treatment only with CF₃ (right in FIG. 2) usually results in a higher contact angle hysteresis (the difference between the advancing contact angle and the receding contact angle). Since the monolayer surface-treated only with fluorine is high in hydrophobicity and has great hysteresis in the contact angle of water drops, it is not easy to implement the cleaning effect when water drops roll down by gravity, collecting dust and the like from the surface. While the contact angle hysteresis is highly reduced as in the mixed self-assembled monolayer (left in FIG. 2), self-cleaning effect is implemented to enhance contamination resistance.

The domains formed by the CF₃ functional groups higher in the frictional force are shown as brighter islands on the image through the friction atomic force microscope which reacts more sensitively with the other components on the surface (frictional force: CF₃>CH₃, CF₃ is shown relatively brighter in color) (FIG. 3, A8). For the comparative example formed only with CF₃, there was no relative difference, so that there was no particular difference in brightness and uniform brightness was exhibited (FIG. 3, A9). In the image obtained by a topographic atomic force microscope which shows surface roughness or step difference, no significant difference was shown because there was a small step difference. As such, with spontaneous phase separation which occurs in the surface reaction process of two types of organic silane, a surface of greater hydrophobicity can be implemented than using normal fluorine groups.

Therefore, there is provided a method of producing a highly hydrophobic surface in a simple and efficient manner, and, in addition, having an effect applicable to the fields which require surface properties, e.g., contamination resistance, heat resistance, chemical resistance, abrasion resistance, durability, etc. In particular, the highly hydrophobic surface having heat resistance, chemical resistance, abrasion resistance and durability as described above is usefully applicable to the study of behavior for thermal, chemical and mechanical factors on a polymer thin film or on a surface with low surface energy, and useful for fields only requiring contamination resistance.

It will be apparent to those skilled in the art that the foregoing description was illustrated in detail for the embodiment and the comparative example, but variations and modifications can be made within the scope of the disclosure and should be covered by the appended following claims. The disclosure resides in each and every novel characteristic feature and each and every combination of the features. The use of the verb “to comprise” and its conjugations does not exclude the presence of elements other than those stated in the claim. The use of the article “a” or “an” preceding an element does not exclude the presence of a plurality of such elements.

1-7. (canceled)

8. A method for treating a surface of a substrate, comprising:
forming a layer on the surface via chemical vapor deposition with a CF₃-functionalized organic silane and a CH₃-functionalized organic silane,
wherein the length of a carbon chain of the CH₃-functional organic silane is shorter than a carbon chain of the CF₃-functionalized organic silane.

9. The method of claim 8, wherein the layer is a mixed self-assembled monolayer (SAM).

10. The method of claim 8, wherein the substrate is selected from the group consisting of quartz, silicon wafer, glass, ceramic, glass-ceramic, inorganic metallic oxide, activated plastic, and a layer thereof.

11. The method of claim 8, further comprising implementing phase separation during bonding between the surface and the CF₃-functionalized organic silane, and between the surface and the CH₃-functionalized organic silane.

12. The method of claim 8, wherein the CF₃-functionalized organic silane has the following chemical formula:
F₃C(CF₂)ₐ(CH₂)_{b}SiX₃, and
the CH₃-functionalized organic silane has the following chemical formula:
H₃C(CH₂)_{c}SiX₃,
wherein a is 5 to 20; b is 2 to 5; c is 7 to 23; and each X is independently selected from the group consisting of chloride, methoxy and ethoxy.

13. The method of claim 8, wherein each X is the same.

14. The method of claim 8, wherein the difference in the number of carbons in a carbon chain of the CF₃-functionalized organic silane and of the CH₃-functionalized organic silane is at least 2.

15. The method of claim 14, wherein the layer is highly hydrophobic as measured by a water contact angle of at least 120° and a contact angle hysteresis of not more than 5°.

16. The method of claim 8, further comprising curing the layer.

17. The method of claim 16, wherein curing the layer is carried out at a temperature of 25° C. to 170° C.

18. The method of claim 16, wherein the layer is carried out at a temperature of 80° C. to 150° C. for 1 hour to 5 hours.

19. The method of claim 8, wherein the layer has a surface roughness with a root mean square value of 0.5 nm to 1 nm.

20. A method for treating a surface of a substrate, comprising:
forming a layer on the surface via chemical vapor deposition with a CF₃-functionalized organic silane and a CH₃-functionalized organic silane, wherein the length of a carbon chain of the CH₃-functional organic silane is shorter than a carbon chain of the CF₃-functionalized organic silane;
implementing phase separation during bonding between the surface and the CF₃-functionalized organic silane, and between the surface and the CH₃-functionalized organic silane; and
curing the layer at a temperature of 25° C. to 170° C.

21. The method of claim 20, wherein the layer is a mixed SAM.

22. The method of claim 20, wherein the substrate is selected from the group consisting of quartz, silicon wafer, glass, ceramic, glass-ceramic, inorganic metallic oxide, and activated plastic, and a layer thereof.

23. The method of claim 20, wherein the CF₃-functionalized organic silane has the following chemical formula:
F₃C(CF₂)ₐ(CH₂)_{b}SiX₃, and
the CH₃-functionalized organic silane has the following chemical formula:
H₃C(CH₂)_{c}SiX₃,
wherein a is 5 to 20; b is 2 to 5; c is 7 to 23; and each X is independently selected from the group consisting of chloride, methoxy and ethoxy.

24. The method of claim 20, wherein each X is the same.

25. The method of claim 20, wherein the difference in the number of carbons in a carbon chain of the CF₃-functionalized organic silane and of the CH₃-functionalized organic silane is at least 2.

26. The method of claim 20, wherein the layer is carried out at a temperature of 80° C. to 150° C. for 1 hour to 5 hours.

27. The method of claim 20, wherein the layer has a surface roughness with a root mean square value of 0.5 nm to 1 nm.
